(19) United States
(12) Patent Application Publication
(10) Pub. No.: US 2025/0265307 A1
(43) Pub. Date: Aug. 21, 2025

(54) Numerical Method to Solve the Schrödinger Equation in High-Dimensional Spaces

(71) Applicant: Thomas DUFAUX, Stuttgart (DE)

(72) Inventor: Thomas DUFAUX, Stuttgart (DE)

(21) Appl. No.: 18/581,624

(22) Filed: Feb. 20, 2024

(51) Int. Cl. G06F 17/13

(52) U.S. Cl. CPC G06F 17/13

(57) ABSTRACT

The invention refers to a method for solving the Schrödinger equation ( [symbol] Ψ=EΨ), wherein a Hamilton operator ( [symbol] ) describes the physical problem underlying the eigenvalue problem, the method being adapted to find a corresponding wave function (Ψ) and an energy (E) to solve the eigenvalue problem, the method comprising the following steps: transforming the eigenvalue problem ( [symbol] Ψ=EΨ) into a non-linear differential equation by replacing the wave function (Ψ) by

$$Ψ = g \cdot {e}^{f} \qquad EQN001$$

and inserting EQN011 into the eigenvalue problem, where f is a numerical function which needs to be computed and g is a modulation function, finding a solution for the numerical function (f) in an iterative process, aborting the iterative process when an abort condition is fulfilled, and with the found solution for the numerical function (f), calculating the wave function (Ψ) from EQN011.

### TECHNICAL FIELD

In the development of electronic or mechanical systems, it is state of the art today that these are first modeled in a simulation environment. Only afterwards, prototypes are build-up, samples are ordered, and tests are performed. Simulations accelerate the product development as many faults can be already identified very early in the design phase. This reduces cost in the sample build-up and enables the design of more complex systems.

In contrast chemical/biological/pharmaceutical products are designed by performing long and costly test series. These tests shall for example determine electrical, mechanical or biological material properties. It is often cheaper, faster and more reliable to perform a test, than to perform very complex chemical simulations to attain the same information. But this approach has its limitations.

An example are dyes used in organic solar cells. To build a very efficient solar cell it is important for the dye to have a broad absorption spectra and energy levels which are suitable for an efficient charge transport throughout the solar cell. Absorption spectra can be obtained in experiments with solvated dyes. But upon application in the solar cell, the spectra can narrow, shift, or be quenched. Similar effects can change the energy levels. However, in situ measurements in an assembled solar cell can be very difficult. Therefore, it would be advantageous to directly simulate the behavior of dyes integrated in the solar cell to obtain an ideal efficiency.

To calculate the energy levels the Schrödinger equation must be solved:

$$ℋΨ = E Ψ \qquad EQN001$$

The Hamilton operator [symbol] describes the physical problem. For a given Hamiltonian, the corresponding wave function Ψ and the energy E must be determined.

This kind of equation is an eigenvalue problem. It is especially complicated to solve for quantum mechanical problems. Quantum particles can be at multiple positions simultaneously. Extra dimensions are added to the wave function Ψ to describe all possible combinations of electron positions. With every electron the wave function Ψ is extended by three dimensions. A molecule with 10 electrons is described by a wave function Ψ with 30 dimensions. This complexity generates a workload too high to be handled by any super computer (“Curse of dimensionality”). In some calculations it is also necessary to add dimensions for every atom to consider oscillations between nuclei.

### BACKGROUND ART

The following prior art references are known to the inventor and are relied upon in the following description of the present invention:
LIT001: Modern Quantum Chemistry, A. Szabo, N. Ostlund, 1996 Dover Publication;
LIT002: Fundamentals of Engineering Numerical Analysis, P. Moin, 2010 Cambridge;
LIT003: Finite Elements, S. Ganesan, L. Tobiska, 2017 Cambridge University Press;
LIT004: Numerical Methods for Engineers and Scientists, J. Hoffman, S. Frankel, 2018 CRC Press;
LIT005: JP H10-31685 A—Method for predicting material properties of periodic materials and system for designing/developing periodic materials, 1998;
LIT006: JP 2008/021 259 A—Electronic state simulation method, 2008;
LIT007: JP 2013/156 796 A—Quantum state estimation method for atoms or molecules, etc. in or in vicinity of substance, quantum state estimation device, and computer program, 2013;
LIT008: US 2021/0081804 A1-Tensor network machine learning system, 2021;
LIT009: CN 111 599 414 B-Quantum computer-based full-quantum molecular simulation method, 2020;
LIT010: US 2020/0286595 A1-Simulating electronic structure with quantum annealing devices and artificial neural networks, 2020; and
LIT011: https://en.wikipedia.org/wiki/Bloch % 27s_theorem.

Established methods to solve the Schrödinger equation are (among others) density functional theory (DFT), Hartree-Fock (HF) or numerical methods like QR decomposition. DFT and HF use combinations of known solutions (basis functions). The quality of the results depends strongly on how good the solution resembles the used basis functions. It requires a lot of experience to pick the optimal basis functions for the specific problem and picking less optimal basis functions may create significant, systematic errors. Even so DFT greatly reduces the computational complexity, all these methods are computational demanding. This limits the size of the systems which can be simulated.

Alternatively, eigenvalue problems can be solved numerically (e.g., QR decomposition). These methods provide more precise results because they do not have systematic errors due to basis functions. However, they are computationally even more demanding and scale very badly with many electrons (=dimensions).

New approaches are to use artificial intelligence (AI) to estimate the wave function Ψ or to use quantum computers. An AI also relies on known wave functions Ψ. The more a solution does not match a known solution, the more difficult it is to obtain a good result from an AI. Quantum computers are expected to show a better performance because of their quantum properties. However, they are still in an early development phase and their performance also relies on good algorithms.

### SUMMARY OF THE INVENTION

The invention describes a set of new numerical methods to efficiently solve eigenvalue problems. These methods can be used to solve the Schrödinger equation. More generally they are also applicable to other eigenvalue problems, for example, to calculate normal modes of mechanical elements.

As the invention does not rely on basis functions, the new methods can provide very accurate solutions with very small systematic error. Furthermore, they are very fast, as they do not require computationally intensive, intermediate steps (like solving matrices).

### BRIEF DESCRIPTION OF THE DRAWINGS

Further characteristics and advantages of the present invention are described in further detail hereinafter with reference to the accompanying drawings. These show:

FIG. 1 an iteration scheme to solve the ground state of an eigenvalue problem;

FIG. 2 an iteration scheme to solve an eigenvalue problem for a wave function which includes nodes;

FIG. 3 an example of a box potential with V=−1 for |x|<2.5;

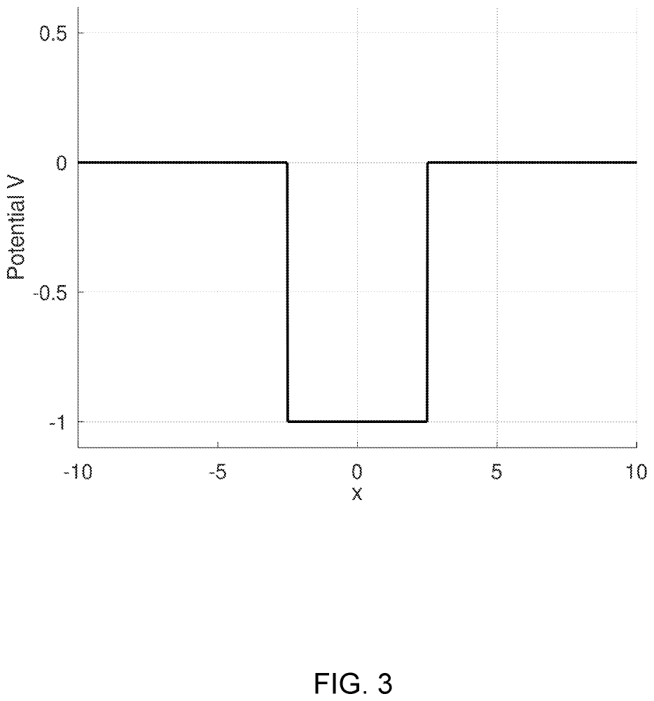

FIG. 4 a wave function Ψ and energy E calculated according to the iteration scheme in FIG. 1 for the potential V in FIG. 3 with the intermediate numerical function f such that the wave function Ψ represents the ground state of the problem;

FIG. 5 a wave function Ψ and energy E calculated according to the iteration scheme in FIG. 2 for the potential V in FIG. 3 with the intermediate numerical function f and the modulation function g such that the wave function Ψ represents the first excited state of the problem;

FIG. 6 an example of the first excited state in the two-dimensional case, where the wave function Ψ was calculated for a circular potential with V=−1 for r<5 with the iteration scheme according to FIG. 2 (this shows the feasibility of the method according to the invention to problems in different dimensions);

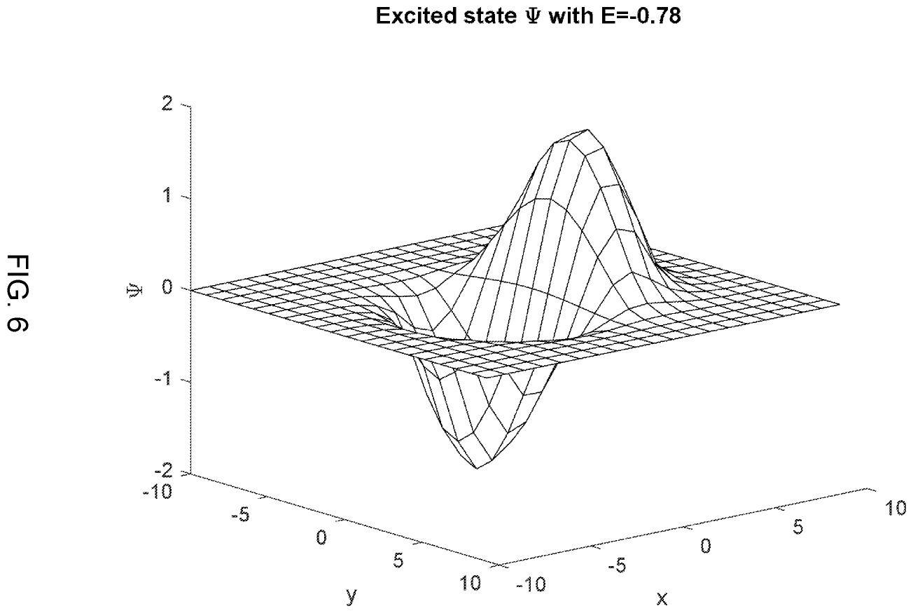

FIG. 7 the real and imaginary part of a wave function Ψ which fulfills the Bloch theorem, calculated for a wave vector k=0.25, and a periodic potential with V=1 for n·L+1<x<n·L+2, where L=3 is the width of the periodic unit cell, and n is an integer; and

FIG. 8 schematic representation of a computation device (10) comprising at least one storage component (12), at least one processor or processing module (14) and at least one IO (input/output) component (16, 18).

### DETAILED DESCRIPTION OF THE INVENTION

Hereinafter a mathematical description of the problem to be solved is introduced. Then, based on this several iteration schemes to solve the Schrödinger equation are derived, wherein solving the Schrödinger equation is only one of many examples for solving any type or kind of eigenvalue problem.

### Mathematical Basics

In the following the Hamilton operator in equation EQN001 is assumed to be

$$ℋ = - \frac{1}{2} {Δ}_{i} - \frac{1}{2 {M}_{A}} {Δ}_{a} + V .$$

This is the operator in its simplest form.

Additional terms can be added, but have to be considered in the development of the iteration scheme. The Laplace-operator (Δ) is the sum of the second order derivatives in all space directions:

$$Δ = \frac{{\partial }^{2}}{\partial {x}^{2}} + \frac{{\partial }^{2}}{\partial {y}^{2}} + \frac{{\partial }^{2}}{\partial {z}^{2}} + \qquad EQN002$$

The subscript of Δ indicates if the dimensions are related to electrons or nuclei. The nuclear part Δₐ is often neglected (see Born-Oppenheimer approximation in LIT001). In the following the nuclear part Δₐ will be neglected to simplify the equations. Thus, it becomes

$$ℋ = - \frac{1}{2} Δ + V ,$$

wherein Δ represents the electron part Δᵢ. An extension is easily possible.

For physical problems, V describes the interactions of the atomic nucleus and electrons:

$$V = - {\underbrace{{\sum }_{i = 1}^{{N}_{e}} {\sum }_{a = 1}^{{N}_{a}} \frac{{Z}_{a}}{{r}_{ia}}}}_{{atom ‐ electron}_{attraction}} + {\underbrace{{\sum }_{i = 1}^{{N}_{e}} {\sum }_{j > i}^{{N}_{e}} \frac{1}{{r}_{ij}}}}_{{electron ‐ electron}_{repulsion}} + {\underbrace{{\sum }_{a = 1}^{{N}_{a}} {\sum }_{b > a}^{{N}_{a}} \frac{{Z}_{a} {Z}_{b}}{{r}_{ab}}}}_{{atom ‐ atom}_{repulsion}} \qquad EQN003$$

The term is extensively described in the literature (for example see LIT001). In principle also other, arbitrary terms are possible for V. As the numerical method does not require V to be of a specific shape the terms shown above are not further discussed here.

To solve the Schrödinger equation, the first step is to transform the eigenvalue problem ( [symbol] Ψ=EΨ) into a non-linear differential equation. To this extent, Ψ is replaced by

$$Ψ = g \cdot {e}^{f} \qquad EQN004$$

and inserted in the eigenvalue problem. f is a numerical function which needs to be computed. g is also a numerical function which is referred as the modulation function within this text. Its significance is explained further below. At the moment we set g=1.

Insertion in the Schrödinger equation

$$( - \frac{1}{2} Δ + V ) Ψ = E Ψ$$

gives:

$$\begin{matrix}{\sum }_{i}^{{N}_{T}} \frac{{\partial }^{2}}{\partial {x}_{i}^{2}} {e}^{f} = - 2 ( E - V ) {e}^{f} \\ {\sum }_{i}^{{N}_{T}} ( {f}_{x i}^{2} + {f}_{x x i} ) = - 2 ( E - V )\end{matrix} \qquad EQN005$$

N_{T} is the number of dimensions, fₓᵢ is the first spatial derivative and fₓₓᵢ is the second spatial derivative along the i^{th} dimension.

To summarize, the ansatz in EQN004 allows to transform the Schrödinger equation in a non-linear equation. A solution of the non-linear problem (EQN005) is also a solution of the Schrödinger equation (EQN001).

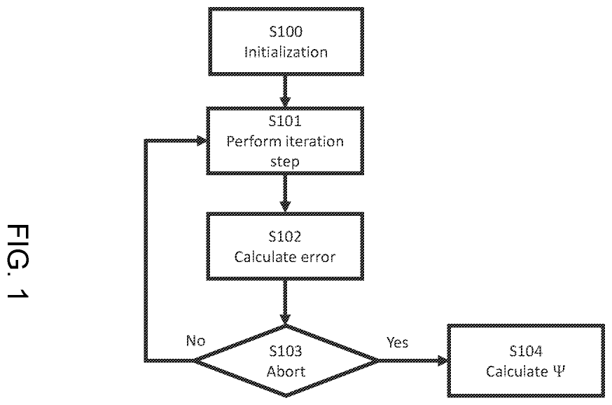

Based on equation EQN005 a method to solve the eigenvalue problem can be set up. The iteration scheme is shown in FIG. 1. In the following the steps are described in detail:

### Step S100—Initialization

a. In the first step S100, initial values for f are selected. Either f is set to zero or a solution can be selected which is expected to be similar to the result. Moreover, a function V is calculated, which describes the problem to be solved. Preferably a potential V according to equation EQN003 is calculated. As mentioned above, the method is not restricted to potentials V given by EQN003, but is applicable to any possible function V.
   Step S101—Perform iteration step
a. There are many approaches to solve non-linear equations like EQN005. Examples are Gauss-Seidel, Successive Over-Relaxation (SOR), the Jacobi method, or the Gauss-Newton algorithm just to name a few (see LIT002, LIT003, or LIT004 for more details on numerical methods). It is noted that these are established methods and are therefore not further discussed here.
b. All these methods have in common to split the problem in many small iteration steps. S101 is such an iteration step. Which method to use depends on the chosen potential V, on the size of the problem to be solved and on the used computation device.
   Step S102—Calculate error
a. The error is determined from the non-linear equation EQN005 by computing the difference of the left- and right-hand side. In case of an exact solution this difference is zero. If the difference is non-zero or above a threshold, then probably not enough iteration steps have been performed yet.

### Step S103—Abort

a. In this step S103 the abort conditions are evaluated. It is checked if the error is below a target threshold. In this case no further iterations are needed and the scheme jumps to step S104. Another abort condition could be to check if an upper limit of iteration steps is reached to avoid infinite loops (for example if the problem does not converge). It also makes sense to test for numerical errors (e.g., infinite in the solution) to detect overflow conditions or divisions by zero.

Step S104—Calculate Wave Function Ψ
a. In the last step S104 the wave function Ψ is calculated according to the ansatz defined in EQN004. It is optional to normalize the wave function Ψ in this step S104. However, it should be considered that the solution might not be correct, depending on which abort criterium was evaluated in step S103.

### Differences to Other Known Methods

A similar approach to transform a differential equation in another one is given by the Riccati equation. This equation can be transformed to a one-dimensional Schrödinger equation. However, it is restricted to the one-dimensional case, while the ansatz in EQN004 is also applicable to problems with more dimensions (e.g., 2D, 3D, or even more dimensions). This is important as the potential of real physical problems (see EQN003 for a typical potential of a set of atoms and electrons) is in general of high dimensionality.

The new method has another major advantage which is only given implicitly. Usually, differential equations need a set of boundary conditions (for example Neumann or Dirichlet boundary conditions) to have a unique solution. Without them the set of differential equations cannot be solved and results usually diverge.

In contrast thereto, the iteration scheme described in FIG. 1 does not set any boundary conditions. By choosing the ansatz of EQN004 the solution space is already reduced such that further boundary conditions are not needed. The solution f out of the scheme above has only one degree of freedom left which is a constant offset. The offset is (again implicitly) chosen when the wave function Ψ is normalized in step S104. This is illustrated in the next equation:

$$θ \cdot Ψ = {e}^{f + log ( θ )}$$

If a wave function Ψ is scaled by a constant factor θ in order to normalize it, then this is equivalent to adding an offset of log(θ) to numerical function ƒ.

To be able to solve the Schrödinger equation without specifying boundary conditions is of great technical importance. As described above the Schrödinger equation may extend (depending on the problem) over many dimensions, which makes its computation very intensive in terms of time and processing power. To reduce the computational effort, the solution space shall be reduced to a minimum. To this end, it is suggested that the computer implemented method is configured to consider only areas in space of the wave function which have a significant contribution to the solution, for example a contribution on the energy. In general, this is possible because large portions of this space are empty or do not significantly contribute to the solution. However, if only a sub-space of the Schrödinger equation is solved with other methods, then boundary conditions have to be specified along the borders. This is not trivial as the wave function Ψ is not zero along these borders.

The new method of FIG. 1 allows to only calculate sub-spaces and thus to greatly reduce the computational effort. As no boundary conditions need to be specified, a flexible selection of sub-spaces is possible such that only parts which have a significant impact on the solution are computed. A significant impact is given for example, if adding the selected sub-space changes the energy of the solution.

### Excited States

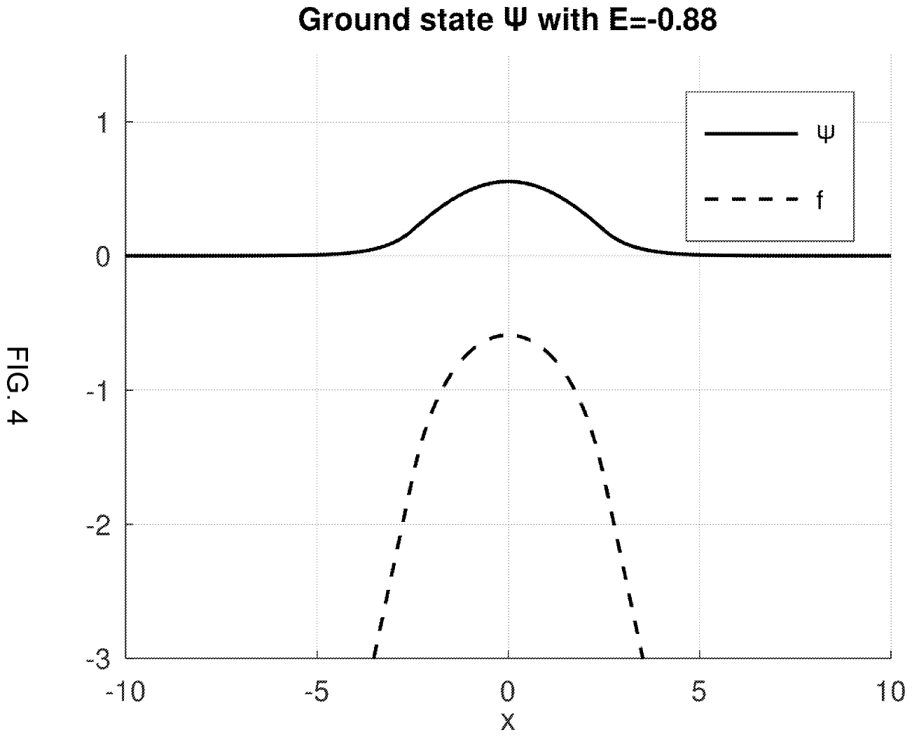

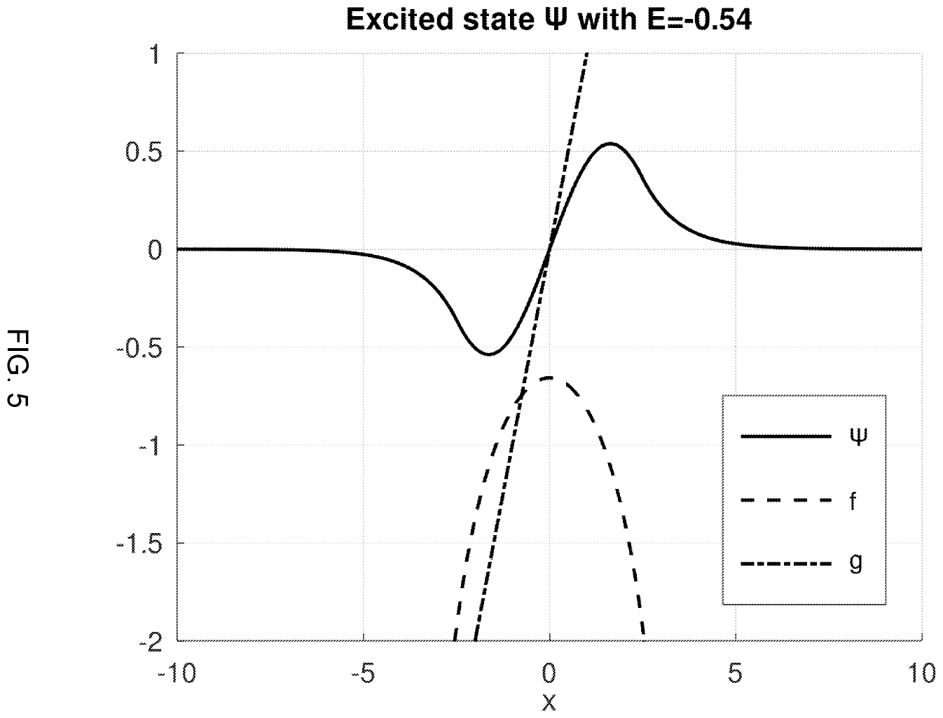

The iteration scheme of FIG. 1 is suitable to solve the ground states of the Schrödinger equation. However, quantum particles can be stimulated to so called excited states. These states are characterized by additional zero crossings (also called nodes) in the wave function. The more nodes within a wave function, the higher is the excited state. As an example, the ground state and the first excited state for the same potential are shown in FIG. 4 and FIG. 5, respectively, in the one-dimensional case. Due to the node in FIG. 5, the energy is higher than in FIG. 4. This property of the wave function Ψ is cause for many physical phenomena like electro-luminescence.

To calculate the excited states of an eigenvalue problem, the modulation function g is used. By picking a suitable function g, nodes are included in the wave function Ψ. Due to the definition in EQN004, the zero points of g are identical to the ones in the wave function Ψ. Aside the zero crossings, g can be chosen freely.

Hereinafter it is described how to determine valid zero points and how the iteration schemes may be modified.

The approach shown above may be repeated, by inserting the ansatz EQN004 in the Schrödinger equation EQN001. However, this time the modulation function g is included. Equivalent to EQN005, the following non-linear differential equation is obtained:

$${\sum }_{i}^{{N}_{T}} ( {f}_{x i}^{2} + 2 \frac{{g}_{x i} {f}_{x i}}{g} + \frac{{g}_{x x}}{g} + {f}_{x x i} ) = - 2 ( E - V ) \qquad EQN006$$

This equation can be solved in a similar manner as EQN005 before. However, in order to solve it, an appropriate modulation function g is needed. As described before, the zero crossings of the modulation function are the nodes of the wave function Ψ. In order to determine g it is sufficient to define the zero crossings. The remaining function can be chosen freely, as long as it remains finite and differentiable.

### There are Two Preferred Approaches to Construct Modulation Functions:

### Use of Analytical Functions:

a. Many problems have symmetries which lead to node surfaces of a (spherical) harmonic shape. The most known are the shapes of the s-, p-, d-, f-, g-, h-orbitals. For these known solutions it is possible to find analytical expressions. They can be used to calculate g. The optimization problem then reduces to identifying the parameters of these functions. Examples are:
b. Spherical (s-orbital):

$$g = \sqrt{{( {x}_{1} - {r}_{1} )}^{2} + {( {x}_{2} - {r}_{2} )}^{2} + …} - R \qquad EQN007$$

c. Planar (p-orbital): g=x₁·n₁+x₂·n₃+ . . . +d
d. . . .

By combining many of these shape functions (e.g., by calculating the product), it is possible to create complex node shapes with just a few parameters.

### Numerical Calculation

a. The function—g can be determined numerically. Possible methods include splines, Bézier-Curves or vectors.

The simplest approach is to keep the modulation function constant and to solve EQN006 in the same way as EQN005. However, this might not give the correct result (the one with the lowest energy). Therefore, the iteration scheme can be extended to adapt the modulation function during the iterative process.

### There are Two Preferred Strategies to Optimize the Modulation Function:

It is possible to adapt the function to optimize for a minimal energy. In this case the shape of the zero crossings is adjusted such that the energy decreases in the next iteration step. This can be achieved by gradient based approaches (see Gauss-Newton Algorithm for example), genetic algorithms or global optimization approaches.

Another approach is to optimize for stability. In this approach the shape of the zero crossing is adjusted such that in the next iteration step the error is reduced. This can be implemented by similar numerical approaches as just the optimization goal is different.

Solving Method with Differentiation for Excited States

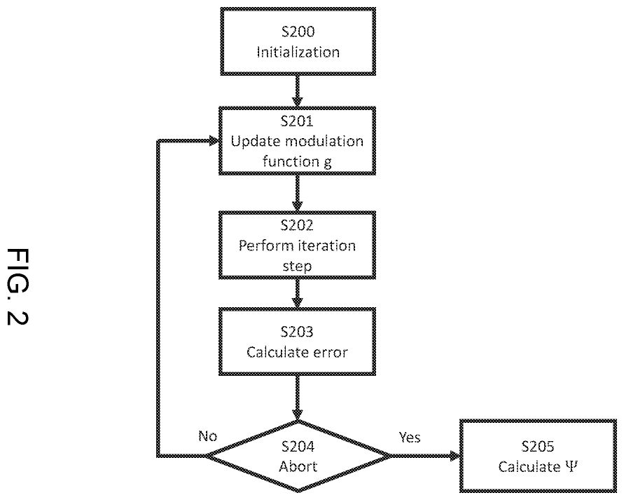

FIG. 2 shows an iteration scheme to solve wave functions Ψ of excited states. It is very similar to the approach shown in FIG. 1. Some steps include additional calculation steps, while others remain unchanged. The following list describes only the changes in respect to the iteration scheme of FIG. 1:

### Step S200—Initialization

a. Aside the initialization of ƒ, in this step S200 also values for the modulation function g must be selected. One possibility is to find a first solution by using symmetries of the problem. For example, node surfaces often are aligned along mirror symmetrical axes of the potential.

### Step S201—Update Modulation Function g

a. If the modulation function g is fixed, this step can be omitted. Otherwise, the modulation function g is updated, depending on the chosen optimization goal. The shape of the zero crossing can be changed, for example by adaption of the parameters of the analytical functions in EQN007.

### Step S202—Perform Iteration Step

a. This step is similar to step S101. Instead of EQN005 now the non-linear equation EQN006 must be updated in this step with the latest modulation function.

### Step S203—Calculate Error

a. This step is identical to step S102

### Step S204—Abort

a. This step is identical to step S103

### Step S205—Calculate Wave Function Ψ

a. In the last step S205, the wave function Ψ is calculated with the ansatz EQN004. Of course, the latest modulation function g must be used. As in step S104 it is possible to normalize the wave function Ψ in this step S205.

### Periodic Boundary Conditions

The atoms in crystals are arranged in a highly periodic manner. Many physical effects (especially in solid state physics) are caused by the periodicity. It determines the wave functions in solid materials. Periodic systems can be well described by imposing periodic boundary conditions along spatial dimensions. The main idea is that only the unit cell (which is the minimum space to be repeated to create the periodic potential) is fully computed. Similar approaches are used for other periodic numerical problems.

According to Bloch's theorem (see LIT011) a wave function Ψ in a periodic potential must have the form

$$Ψ ( \vec{r} ) = {e}^{i \vec{k} \cdot \vec{r}} u ( \vec{r} ) \qquad EQN008$$

where \vec{r} is a position vector and \vec{k} is a wave vector. Wave functions of this shape can be obtained from the iteration scheme in FIG. 1 and FIG. 2. To achieve it, a boundary condition must be added to the iteration scheme in steps S101 and S201. At the border the wave function Ψ must have a phase shift of the form Ψ(rᵢ+Lᵢ)=e^{ik}^{ᵢ}^{·L}^{ᵢ}·Ψ(rᵢ) where rᵢ, Lᵢ and kᵢ are the position, unit cell size and wave vector of dimension i respectively. This will give a complex valued wave function which fulfills the Bloch theorem in EQN008.

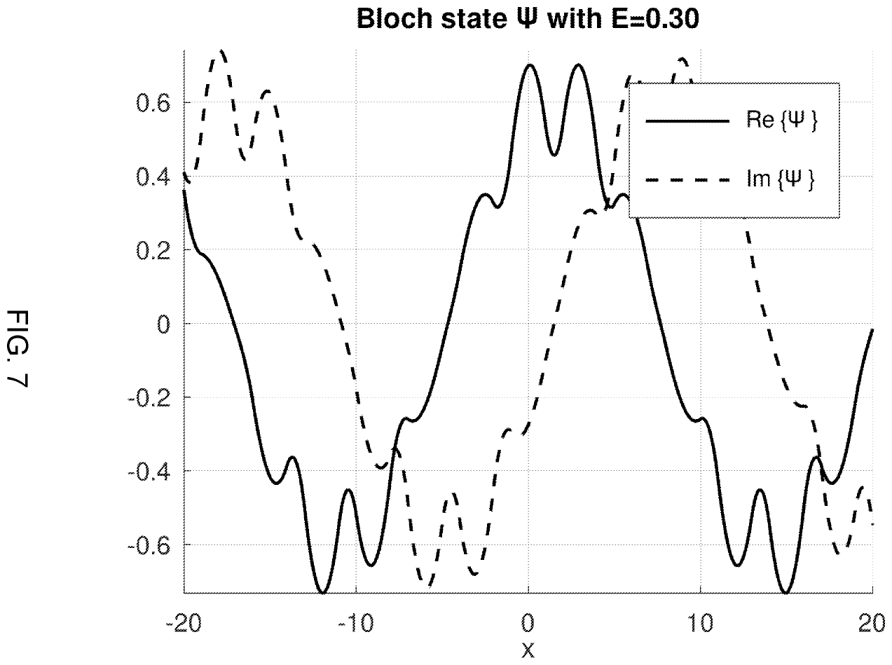

In FIG. 7 an example of a wave function which fulfills EQN008 is shown. It is calculated for a periodic potential, with V=1 for n·L+1<x<n·L+2. L is the width of the unit cell (L=3 in this case), n is an integer and the wave vector is k=0.25. The wave function is not periodic with the unit cell. The Bloch theorem states, that the wave function must have a constant phase shift from unit cell to unit cell.

### Classical and Quantum Computing

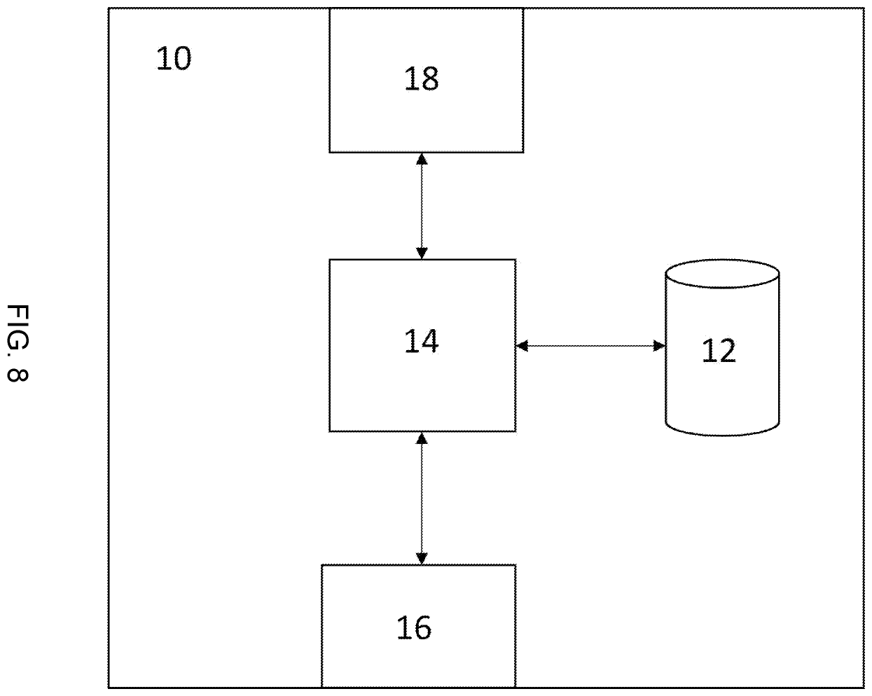

The iteration schemes described herein are preferably implemented in a computation device 10, which is schematically shown in FIG. 8. Such a device 10 consists of one or more storage components 12 (e.g., RAM, ROM, magnetic, optical storage), one or more processing components 14 (e.g., CPU (central processing unit), GPU (graphical processing unit), QPU (quantum processing unit)), and one or more IO (input/output) components 16, 18 (e.g., networks, screens, keyboards). The problem to solve is provided to the computation device 10 over one or more of the IO components 16, 18. This can be a request over a network, a user input or an automated calculation (for example database scans for molecules with specific properties). Storage components 12 are needed to save the intermediate functions during the calculation process and to store the final results when the computation is completed. Depending on the size of the problem, the calculation can be split among multiple processing components 14 (e.g., CPUs and GPUs) in order to obtain a fast solver implementation even for large problems. The final results may be distributed again via the IO components 16, 18.

Especially the implementation with QPUs is of interest. Instead of spanning the numerical function f over many dimensions, it is possible to superimpose possible solutions of ƒ and g. This would significantly reduce the computation effort and be a fundamental advantage over computation with CPUs. In this case also a reduction to relevant spatial regions is not necessary. The combination of computing the full solution space and using a numerical method without including a priori knowledge would give very precise results.

There are many different types of quantum computers in use and it remains to be seen which type will prevail. A possible implementation could use a quantum annealing device to solve the non-linear equations or to optimize the modulation function. In general, a quantum annealer solves an optimization problem of the form

$$H ( s ) = A ( s ) {\underbrace{{\sum }_{i}}}_{{H}_{I}} {σ}_{i}^{x} + B ( s ) {\underbrace{( {\sum }_{i} {h}_{i} {σ}_{i}^{z} + {\sum }_{i < j} {J}_{ij} {σ}_{i}^{z} {σ}_{j}^{z} )}}_{{H}_{F}} \qquad EQN009$$

The problem H(s), where s is the annealing parameter, is optimized to find its minimum value. H_{I} is the initial Hamiltonian and H_{F} is the final Hamiltonian. During the annealing process the function A(s) decreases, while B(s) increases, such that the system state changes from the initial to the final Hamiltonian H_{F}. The initial Hamiltonian is usually filled out automatically. In H_{F}, σ_{i,j} are the Qubits, hᵢ is their bias (the probability that they will collapse to a value +1 or −1), and Jᵢⱼ is the coupling matrix between them. To implement the method above, the non-linear equation must be mapped to the coupling Jᵢⱼ and the bias hᵢ. As, in general, the target wave function shall have a minimum energy, a possible approach is to reformulate the non-linear equation EQN005 for the energy E:

$$E = - \frac{1}{2} {\sum }_{i}^{{N}_{T}} ( {f}_{x i}^{2} + {f}_{x x i} ) + V \qquad EQN010$$

The same approach is possible with EQN006. Then the coupling factors Jᵢⱼ in EQN009 are chosen to match the right-hand side of EQN010. hᵢ can be used to impose boundary conditions if needed. This way the thermal annealer computes the energy and the wave function as part of its optimization process. The optimization of the modulation function can be implemented in the same way and can even be combined in one optimization run.

1. A computer implemented method for solving an eigenvalue problem to determine at least a wave function and energy of a quantum particle by solving the Schrödinger equation, wherein the computer implemented method is realized in the form of a computer program executable on a processor or processing module (14), which is configured to solve a non-linear equation which is obtained by using the ansatz ψ=e^{ƒ} for the wave function, with a numerical function f, when executed on the processor or processing module (14).

2. The computer implemented method according to claim 1, wherein the computer implemented method is configured to realize at least the following steps, when the computer program is executed on the processor or processing module (14):
(S100) setting initial values for the numerical function ƒ;
(S101) performing an iteration step to solve the non-linear differential equation in order to obtain a solution for the numerical function ƒ;
(S102) calculating the remaining error of the non-linear differential equation;
(S103) testing of abort conditions, comprising whether the error is below a threshold; and
(S104) taking the solution for the numerical function f and using the ansatz ψ=e^{ƒ} to calculate and obtain the wave function.

3. The computer implemented method according to claim 1, wherein the computer implemented method is configured to solve the ground state of the Schrödinger equation, when the computer program is executed on the processor or processing module (14), wherein the numerical function f is a real numerical function, such that the wave function does not include nodes.

4. The computer implemented method according to claim 1, wherein the computer implemented method is configured to determine the wave function for periodic potentials, when the computer program is executed on the processor or processing module (14), wherein a complex phase boundary condition is implemented such that a resulting wave function fulfills the Bloch theorem.

5. The computer implemented method according to claim 1, wherein the computer implemented method is configured to use a numerical function f which has complex values, when the computer program is executed on the processor or processing module (14), such that the resulting eigenfunction also consists of complex values.

6. The computer implemented method according to claim 1, wherein the computer implemented method is configured to solve eigenvalue problems with eigenfunctions of different dimensionality, ranging from one to a plurality of dimensions.

7. The computer implemented method according to claim 6, wherein the computer implemented method is configured to consider only areas in space of the wave function which have a significant contribution to the solution, comprising a contribution on the energy.

8. A computer implemented method for solving an eigenvalue problem to determine among other things the wave function and energy of a quantum particle by solving the Schrödinger equation, wherein the computer implemented method is realized in the form of a computer program executable on a processor or processing module (14), which is configured to solve a non-linear equation which is obtained by using the ansatz ψ=g·e^{ƒ} for the wave function, with the modulation function g and a numerical function ƒ, when executed on the processor or processing module (14).

9. The computer implemented method according to claim 8, wherein the computer implemented method is configured to realize at least the following steps, when the computer program is executed on the processor or processing module (14):
(S200) setting initial values for the numerical function f and the modulation function g;
(S201) updating of the modulation function g, which is omitted if the modulation is fixed;
(S202) performing an iteration step to solve the non-linear differential equation in order to obtain a solution for ƒ;
(S203) calculating the remaining error of the non-linear differential equation;
(S204) testing of abort conditions, for example if the error is below a threshold; and
(S205) taking the solution f, the latest updated modulation function g and using the ansatz ψ=g·e^{ƒ} to calculate and obtain the wave function.

10. The computer implemented method according to claim 8, wherein the computer implemented method is configured to use a modulation function g which contains a single or multiple zero crossings which introduce nodes in a resulting wave function ψ.

11. The computer implemented method according to claim 10, wherein the computer implemented method is configured to use a modulation function g, which includes zero crossings of at least one of a spherical, rectangular, conical, or planar shape.

12. The computer implemented method according to claim 10, wherein the computer implemented method is configured to use a modulation function g, which includes zero crossings computed by numerical methods, comprising Bézier-curves or splines.

13. The computer implemented method according to claim 10, wherein the computer implemented method is configured to have a fixed modulation function g, which does not change during the determination of the eigenfunction.

14. The computer implemented method according to claim 10, wherein the computer implemented method is configured to update the modulation function g during the determination of the wave function to find the optimal node shape.

15. The computer implemented method according to claim 14, wherein the computer implemented method is configured to optimize a position of zero crossings in the modulation functions g such that a resulting energy of the eigenvalue problem is minimized.

16. The computer implemented method according to claim 14, wherein the computer implemented method is configured to optimize a position of zero crossings in the modulation functions g such that a calculation of the resulting wave function converges and that there are no parts of the resulting wave function with growth to infinity.

17. The computer implemented method according to claim 8, wherein the computer implemented method is configured to solve eigenvalue problems with eigenfunctions of different dimensionality, ranging from one to many dimensions.

18. The computer implemented method according to claim 17, wherein the computer implemented method is configured to consider only areas in space of the wave function which have a significant contribution to the solution, comprising a contribution on the energy.

19. Computation device (10) comprising at least one storage component (12), at least one processor or processing module (14) and at least one IO (input/output) component (16, 18), wherein the computation device (10) is configured to receive an eigenvalue problem to be solved over the at least one IO component (16), and the computation device (10) further comprises a computer program configured to be executed on the at least one processor or processing module (14) and programmed to realize the computer implemented method according to claim 1 when executed on the at least one processor or processing module (14).

20. Computation device (10) according to claim 19, wherein a quantum processing unit is used to minimize the non-linear differential equation, which superimposes quantum states to reduce the dimensionality of the problem.

21. Computation device (10) according to claim 20, wherein the method is implemented in a quantum annealer to solve the non-linear differential equation, in order to obtain the wave function and energy.

22. Computation device (10) according to claim 19, wherein the eigenvalue problem to be solved is a request over a network, a user input or an automated calculation, all received by the computation device (10) through the at least one IO component (16, 18) of the computation device (10).

23. Computation device (10) according to claim 19, wherein the automated calculation comprises database scans for molecules with specific predefined properties.
